(19) United States
(12) Patent Application Publication
(10) Pub. No.: US 2007/0238323 A1
(43) Pub. Date: Oct. 11, 2007

(54) ELECTRICAL CONNECTOR AND TERMINAL THEREFOR

(75) Inventors: Alexander R. Mathews, Austin, TX (US); Johannes P.M. Kusters, Cedar Park, TX (US); Juan P. Rios, Austin, TX (US); Kevin R. Meredith, Loretto, KY (US); Alexander W. Barr, Austin, TX (US); Richard J. Scherer, Austin, TX (US); Steven Feldman, Cedar Park, TX (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 11/690,004

(22) Filed: Mar. 22, 2007

Related U.S. Application Data
(60) Provisional application No. 60/813,620, filed on Apr. 11, 2006.

(51) Int. Cl. H05K 1/00

(52) U.S. Cl. 439/65

(57) ABSTRACT

A terminal for use in an electronic connector for establishing electrical contact with a conductive surface on a first printed circuit board. The terminal includes a base section configured for electrical connection with a second printed circuit board, and a resilient contact beam having a proximal end coupled to the base section and a free distal end. The contact beam is shaped to provide a contact section between the proximal end and the distal end. The contact section is configured for engaging the conductive surface on the first printed circuit board upon insertion of the first printed circuit board into the housing in a first direction. The free distal end of the contact beam extends substantially in the first direction.

### REFERENCE TO CROSS-RELATED APPLICATIONS

The present application claims priority to U.S. provisional Patent Application 60/813,620, filed Apr. 11, 2006.

### FIELD

The present disclosure relates generally to interconnections made between two printed circuits, such as printed circuit boards (PCBs).

### BACKGROUND

The interconnection of printed circuit boards to other circuit boards is well known in the art. In particular, it is well known to provide electrical connector sockets for interconnecting a first printed circuit board to a second printed circuit board. Typically, the sockets are formed to include an elongated slot and a plurality of electrical terminals coupled to the housing adjacent to the slot. When the edge of the daughtercard (i.e., the first printed circuit board) is inserted into the slot of the socket, conductive surfaces on the daughtercard engage the terminals to couple the daughtercard to the socket electrically. The terminals are also coupled to conductive traces on the motherboard (i.e., the second printed circuit board) so that when the daughtercard is inserted into the socket, the daughtercard is electrically coupled to the motherboard. Exemplary electrical connectors include memory module connectors such as Single In-line Memory Module (SIMM) connectors, Dual In-line Memory Module (DIMM) connectors, and Double Data Rate (DDR) connectors. The electrical connectors may sometimes be referred to as “edge connectors,” as the conductive surfaces on the daughtercards are commonly adjacent an edge of the printed circuit board.

Typically, the electrical terminals comprise cantilever beam-type contacts pointing upward from (i.e., away from the surface of) the motherboard on which the electrical connector is mounted. Because the contact beams point away from the surface of the motherboard, there is a limit to how close to the motherboard the contact point between the terminals and the conductive surfaces of the daughtercard can be positioned. In particular, the contact beams must be long enough to provide the necessary contact force and range of motion to accommodate the thickness of the daughtercard without suffering permanent deformation. However, it is desirable to minimize the distance between the contact point of the contact beams and the surface of the motherboard (i.e., the contact distance) for several reasons. Minimizing the contact distance allows the connector and daughtercard to be contained in a smaller space, or allows a larger daughtercard (with additional circuitry, components, etc.) to be used in the available space.

### SUMMARY

In one aspect, the invention described herein provides a terminal for use in an electronic connector for establishing electrical contact with a conductive surface on a first printed circuit board, the connector including a housing having a plurality of terminal-receiving cavities. In one embodiment, the terminal comprises a base section and a resilient contact beam. The base section is configured for electrical connection with a second printed circuit board. The contact beam has a proximal end coupled to the base section and a free distal end. The contact beam is shaped to provide a contact section between the proximal end and the distal end. The contact section is configured for engaging the conductive surface on the first printed circuit board upon insertion of the first printed circuit board into the housing in a first direction. The free distal end of the contact beam extends substantially in the first direction.

In another aspect, the invention described herein provides an electrical connector for receiving a first printed circuit board having a plurality of conductive surfaces thereon. In one embodiment, the connector comprises a socket defining an elongated slot having a first side and a second side for receiving the first printed circuit board therein in a first direction. A plurality of electrical terminals is positioned on at least one of the first and second sides of the slot for engaging the plurality of conductive surfaces on the first printed circuit board. The terminals each comprise a contact beam configured for engaging a corresponding one of the conductive surfaces on the first printed circuit board. The contact beam has a free end extending substantially in the first direction.

In another aspect, the invention described herein provides a connector system. In one embodiment, the connector system comprises a first printed circuit board having a plurality of conductive surfaces thereon, a second printed circuit board having a plurality of conductive surfaces thereon, and an electrical connector mounted on the second printed circuit board. The electrical connector comprises a housing defining an elongated slot having a first side and a second side for receiving the first printed circuit board therein in an insertion direction toward the second printed circuit board. A plurality of electrical terminals is positioned on the first and second sides of the slot for engaging the plurality of conductive surfaces on the first printed circuit board. The plurality of electrical terminals is electrically connected to the conductive surfaces on the second printed circuit board. The terminals each include a contact beam configured for engaging a corresponding one of the conductive surfaces on the first printed circuit board. The contact beam has a free end extending substantially toward the second printed circuit board.

### BRIEF DESCRIPTION OF THE DRAWINGS

Embodiments of the invention are better understood with reference to the following drawings. The elements of the drawings are not necessarily to scale relative to each other. Like reference numerals designate corresponding similar parts.

FIG. 1A is a perspective illustration of an electrical connector system according to one embodiment of the invention, showing a daughtercard positioned for insertion in the electrical connector.

FIG. 1B is a perspective illustration of the electrical connector system of FIG. 1A, showing the daughtercard inserted in the electrical connector.

FIG. 2 is a cross-sectional view taken along line 2-2 of FIG. 1B, showing the daughtercard inserted in the electrical connector.

FIG. 3 is a greatly enlarged cross-sectional view of circled portion 3 in FIG. 2.

FIG. 4 is a perspective illustration of the sectioned connector system of FIG. 3.

FIG. 5 is a cross-sectional view similar to FIG. 3, showing the movement of electrical terminals as the daughtercard is withdrawn from the electrical connector.

FIG. 6A is a partial cross-sectional view of an electrical connector system and terminal according to another embodiment of the invention.

FIGS. 6B and 6C are front and side elevational views of the terminal of FIG. 6A.

### DETAILED DESCRIPTION

In the following detailed description, reference is made to the accompanying drawings, which form a part hereof, and in which is shown by way of illustration specific embodiments in which the invention may be practiced. The illustrated embodiments are not intended to be exhaustive of all embodiments according to the invention. It is to be understood that other embodiments may be utilized and structural or logical changes may be made without departing from the scope of the present invention. The following detailed description, therefore, is not to be taken in a limiting sense, and the scope of the present invention is defined by the appended claims.

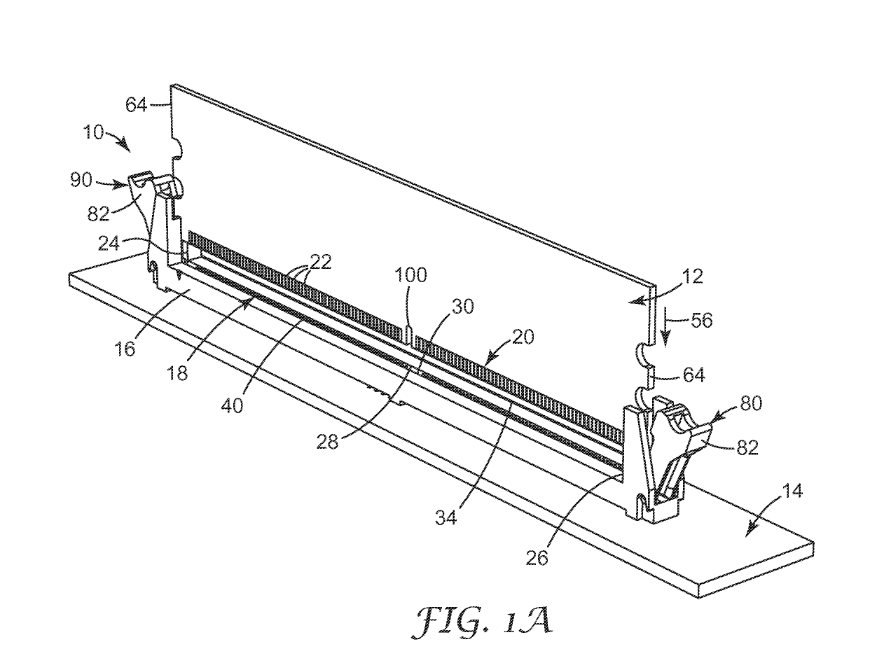

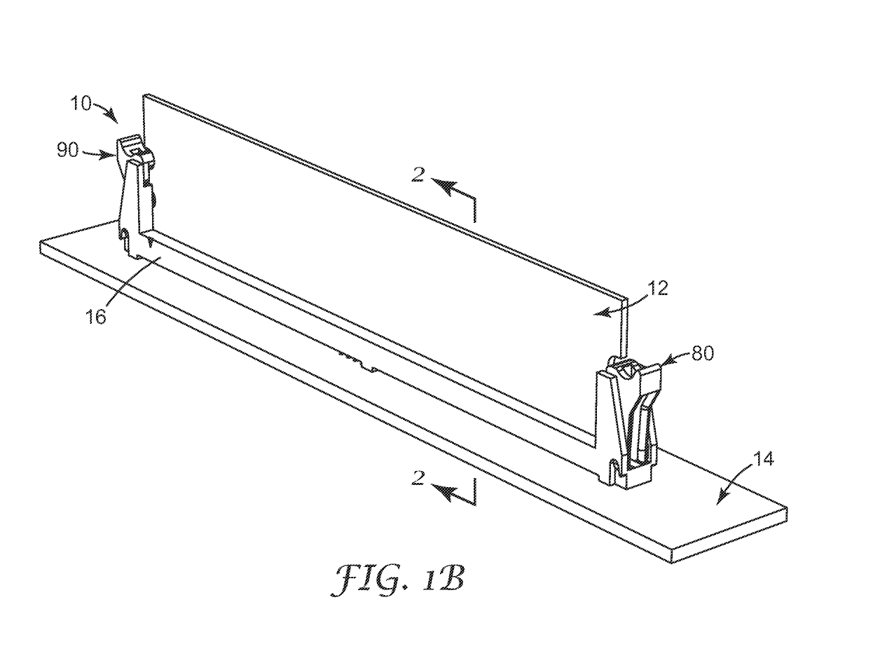

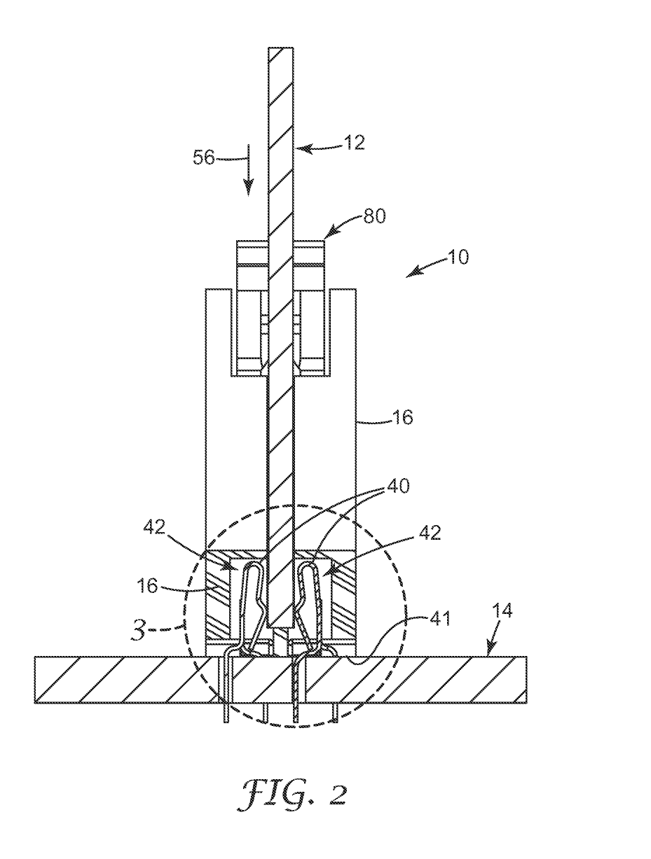

Referring to FIGS. 1A and 1B, one embodiment of a socket connector 10 for interconnecting a first printed circuit board (i.e., daughtercard) 12 to a second printed circuit board (i.e., mother board) 14 according to the present invention is illustrated. Socket 10 includes a housing 16 formed to include an elongated slot 18 therein for receiving a bottom edge portion 20 of daughtercard 12 having conductive surfaces 22 thereon. Slot 18 extends from a first end 24 to an opposite second end 26, and further includes a first side 28 and an opposite second side 30 spaced apart from first side 28. A bottom surface 32 of slot 18 (seen in FIGS. 2-4) is configured to engage a bottom edge 34 of daughtercard 12 as daughtercard 12 is inserted into slot 18.

As best seen in FIGS. 2-4, socket 10 includes a plurality of contact terminals 40 for engaging conductive surfaces 22 on daughtercard 12 when daughtercard 12 is inserted into slot 18 of socket 10. Terminals 40 are positioned on at least one of first and second sides 28, 30 of slot 18, and are positioned in terminal-receiving cavities 42 of housing 16, which open along a bottom mounting surface 41 of the housing 16. Terminal receiving cavities 42 are defined by spaced apart partitions or walls 43. Each terminal-receiving cavity 42 can receive a single terminal 40, or can receive more than one terminal 40. In one embodiment, terminals 40 are positioned on both first and second sides 28, 30 of slot 18. In other embodiments, terminals 40 are positioned on only one of first and second sides 28, 30 of slot 18.

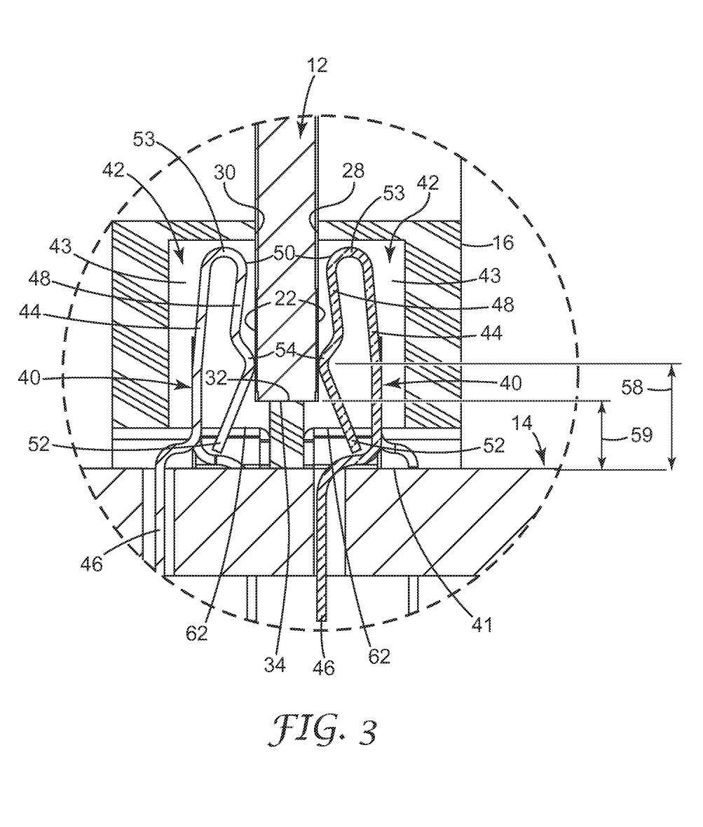

Terminals 40 each include an upwardly extending base section 44 having a contact tail 46 for electrically coupling terminals 40 to one or more of a plurality of signal and ground traces and planes of the motherboard 14 (FIG. 3). A downwardly extending resilient contact beam 48 has a proximal end 50 coupled to the base section 44 and a free distal end 52. In the illustrative embodiment of FIGS. 1-4, proximal end 50 is coupled to base section 44 by U-shaped portion 53, although any suitable coupling between proximal end 50 and base portion 44 may be used. The free distal end 52 of the contact beam 48 extends substantially toward motherboard 14. Walls 43 of terminal-receiving cavity 42 are spaced apart by a distance sufficient to allow free movement of at least the contact beam 48. In some embodiments, base section 44 of terminal 40 is provided with retention features (not shown) that engage housing 16 to retain terminal 40 within terminal-receiving cavity 42, such as by press-fit between walls 43.

The contact beam 48 is shaped to provide a contact section 54 between proximal end 50 and free distal end 52. Contact section 54 extends into slot 18 to engage one of conductive surfaces 22 on opposite sides of daughtercard 12 when daughtercard 12 is inserted into slot 18 in the direction of arrow 56. In one embodiment, contact section 54 comprises a curved portion of contact beam 48 that extends toward slot 18 in a direction substantially transverse to the insertion direction (e.g., substantially transverse to the direction of arrow 56) of daughtercard 12.

Because free distal end 52 of beam 48 extends substantially toward mother board 14, rather than away from mother board 14, it is possible to minimize the distance between the contact section 54 of contact beam 48 and the surface of mother board 16 (i.e., the contact distance 58), and also minimize the distance between bottom edge 34 of daughtercard 12 and the surface of mother board 14 (i.e., the seating distance 59). Minimizing the contact distance and seating distance allows the socket 10 and daughtercard 12 to be contained in a smaller space, or allows a larger daughtercard 12 (with additional circuitry, components, etc.) to be used in the available space. In one embodiment, the seating distance 59 is less than about 3 mm. In another embodiment, the seating distance 59 is less than about 1.5 mm.

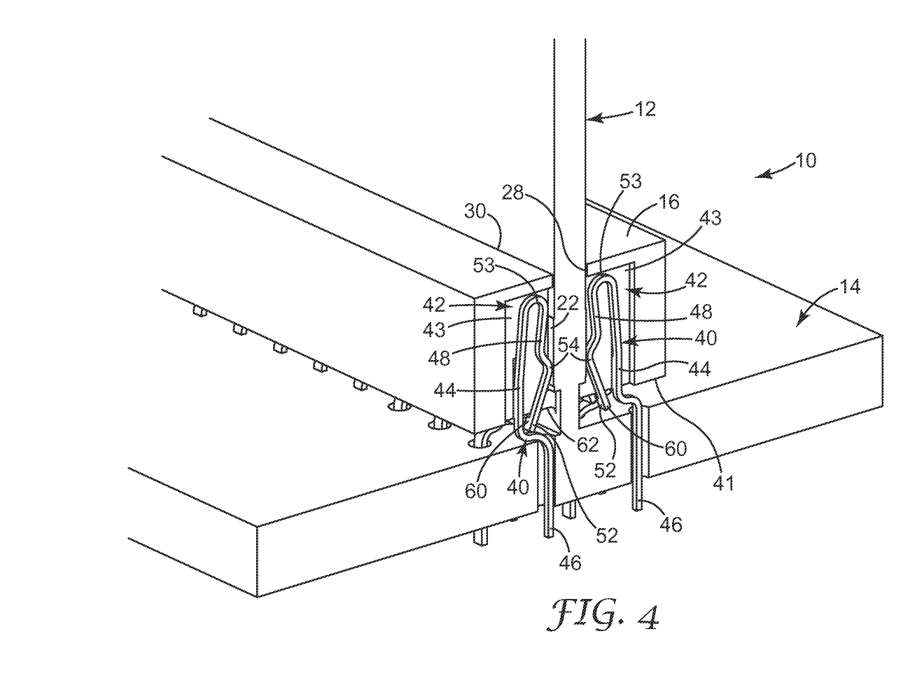

As best seen in FIG. 4, free distal end 52 of contact beam 48 is provided with a tip capture portion 60. Tip capture portion 60 is configured to remain spaced from housing 16 when daughtercard 12 is inserted into slot 18 in the direction of arrow 56, and to engage housing 16 when daughtercard 12 is withdrawn from housing 16 in a direction opposite the insertion direction (e.g., opposite the direction of arrow 56). In one embodiment, free distal end 52 of contact beam 48 extend below a bottom surface 62 of walls 43 of terminal-receiving cavity 42, and tip capture portion 60 comprises an enlarged head that is too large to fit between walls 43 (i.e., tip capture portion 60 prevents free distal end 52 from entering terminal-receiving cavity 42).

As daughtercard 12 is inserted into slot 18 of socket 10 in the direction of arrow 56, bottom edge 34 and then conductive surfaces 22 of daughtercard 12 engage contact sections 54 of terminals 40. As they are displaced, contact beams 48 apply a force normal to daughtercard 12. During insertion of daughtercard 12, friction forces between contact sections 54 and daughtercard 12 will also tend to urge contact sections 54 in the insertion direction of arrow 56. Accordingly, free distal ends 52 of contact beams 48 are also moved generally in the insertion direction toward the surface of motherboard 14, such that tip capture portions 60 remain free of engagement with housing 16. Insertion of daughtercard 12 is halted when bottom edge 34 of daughtercard 12 engages bottom surface 32 of slot 18.

To align conductive surfaces 22 on daughtercard 12 with terminals 40 of socket 10, socket 10 and daughtercard 12 can be provided with alignment or guided means as are known in the art. For example, a side edge 64 of daughtercard 12 may be biased against one of first and second ends 24, 26 of slot 18.

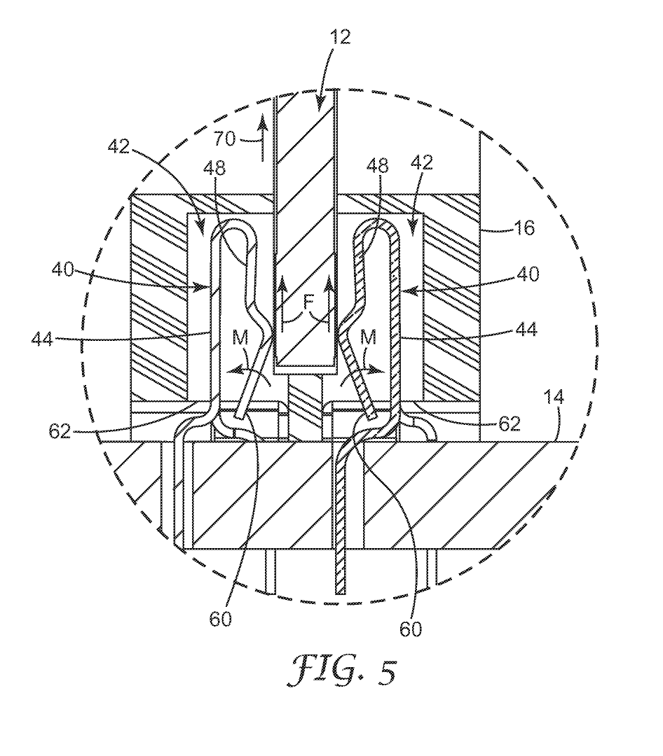

Referring now to FIG. 5, when it is desired to remove daughtercard 12 from socket 10, daughtercard 12 is moved in the direction of arrow 70. Friction forces F between contact sections 54 and daughtercard 12 tend to urge contact sections 54 in the withdrawal direction of arrow 70. Accordingly, free distal ends 52 of contact beams 48 are also moved generally in the withdrawal direction of arrow 70. As free distal ends 52 move upward with the withdrawal of daughtercard 12, tip capture portions 60 engage bottom surfaces 62 of walls 43 of terminal-receiving cavities 42 in housing 16. Engagement of tip capture portions 60 with housing 16 stops further upward movement of free distal ends 52 and contact sections 54. However, friction force F between contact sections 54 and daughtercard 12 remains as withdrawal of daughtercard 12 continues. As seen in FIG. 5, the point of engagement between tip capture portions 60 and housing 16 is spaced apart from the plane of daughtercard 12. Accordingly, friction force F applied to beams 48 at contact sections 54 attempts to rotate terminals 40 about the point of engagement between tip capture portions 60 and housing 16 when daughtercard 12 is withdrawn from slot 18. Put another way, the location of the point of engagement between tip capture portion 60 with housing 16, and the location and direction of friction force F creates a moment M that reduces the normal force between contact section 54 and daughtercard 12 when daughtercard 12 is withdrawn from slot 18.

The reduced normal force between contact section 54 and daughtercard 12 advantageously reduces the force required to withdraw daughtercard 12, and further reduces the possibility of damage to terminal 40. In the absence of tip capture portion 60, friction force F may be sufficient to buckle or otherwise permanently deform terminal 40, thereby rendering socket 10 and potentially motherboard 14 useless.

It is understood that various other terminal configurations may be used in accordance with the present invention. In other words, the present invention is not limited by the specific configuration of terminals 40 shown in FIGS. 1-5. For example, the contact tails 46 of terminals 40 are shown and described herein as through-hole tails. However, the contact tails 46 may also be a surface-mount tails as are known in the art. The terminals 40 of the connector socket 10 may be connected to the motherboard 14 by soldering, press fit, or any other suitable means.

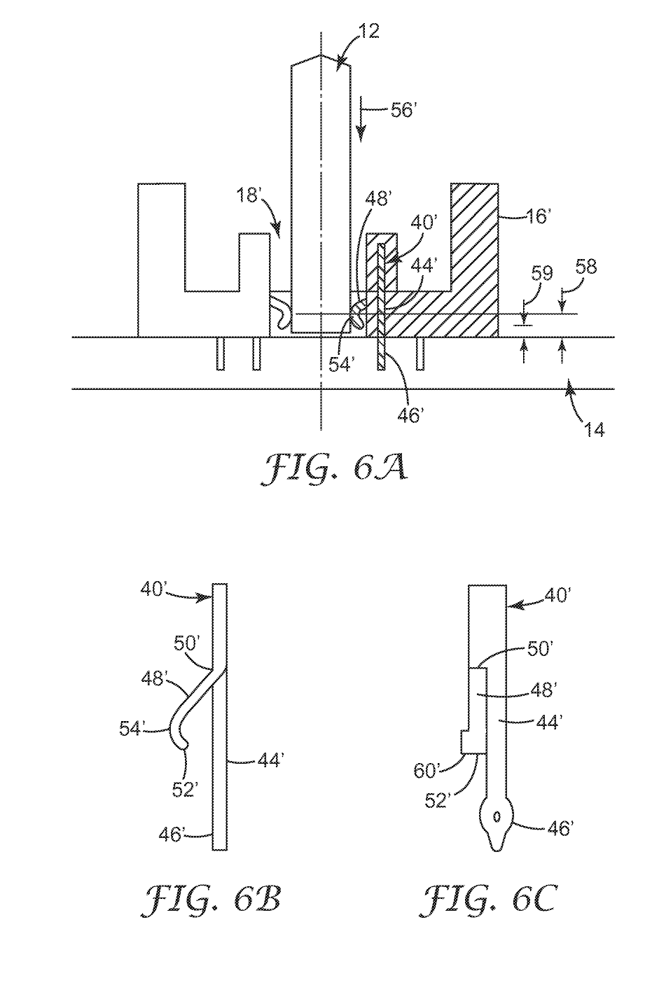

Another embodiment of a terminal 40′ is illustrated in FIGS. 6A-6C. Terminals 40′ are positioned in housing 16′, and each include an upwardly extending base section 44′ having a contact tail 46′ for electrically coupling terminals 40′ to one or more of a plurality of signal and ground traces and planes of the mother board 14. A downwardly extending resilient contact beam 48′ has a proximal end 50′ coupled to the base section 44′ and a free distal end 52′. The free distal end 52′ of the contact beam 48′ extends substantially toward motherboard 14. Housing 16′ is configured to retain terminals 40′, while allowing free movement of at least the contact beam 48′. In some embodiments, base section 44′ of terminal 40′ is provided with retention features (not shown) that engage housing 16′ to retain terminal 40′ within terminal-receiving cavity 42′, such as by press-fit.

The contact beam 48′ is shaped to provide a contact section 54′ between proximal end 50′ and free distal end 52′. Contact section 54′ extends into slot 18′ to engage one of conductive surfaces 22 on opposite sides of daughtercard 12 when daughtercard 12 is inserted into slot 18′ in the direction of arrow 56′. In one embodiment, contact section 54′ comprises a curved portion of contact beam 48′ that extends toward slot 18′ in a direction substantially transverse to the insertion direction (e.g., substantially transverse to the direction of arrow 56′) of daughtercard 12. In one embodiment, free distal end 52′ of contact beam 48′ is provided with a tip capture portion 60′ that functions as described above with respect to tip capture portion 60 of contact beam 48.

For purposes of clarity, the invention is described and illustrated herein as used with printed circuit boards. However, such illustration is exemplary only, and it is understood and intended that the present invention is equally suitable for use with other types of printed circuits including, but not limited to, flexible circuits. It is further understood and intended that different types and configurations of printed circuits may be used simultaneously with the connector assembly 10. For example, the daughtercard may be a printed circuit board, with the motherboard may be a flexible printed circuit.

The electrical connector and terminals thereof are connected to the printed circuit board as is known in the art. The terminals are configured for electrical connection to one or more of a plurality of signal and ground traces and planes of the printed circuit board. Further, although the electrical connector is shown and described herein as a through-hole connector, the connector may also be a surface-mount connector as known in the art. The terminals of the connector may be connected to the printed circuit board by soldering, press fit, or any other suitable means. In one embodiment, the connector is secured to the printed circuit board only by the connection between the terminals and the printed circuit board. In another embodiment, the connector housing includes additional means for securing the connector to the circuit board. For example, the connector housing may include posts configured for insertion into holes (not shown) in the printed circuit board. The posts may be retained in holes in the circuit board by press fit, adhesive, or other suitable means.

In one embodiment, the connector 10 further includes latch means 80 configured to retain the connector 10 and daughtercard 12 in a mated configuration. In one embodiment, the connector 10 further includes ejector means 90 configured to eject the daughtercard 12 from the connector 10. In one embodiment, latch means 80 and ejector means 90 may be operationally joined. For example, disengagement of a lever 82 may disengage latch means 80 and activate ejector means 90. In one embodiment, the connector and daughtercard further include keying and/or polarization means 100 configured to prevent incorrect alignment of connector 10 and daughtercard 12.

In each of the embodiments and implementations described herein, the various components of the connector assembly and elements thereof are formed of any suitable material. The materials are selected depending upon the intended application and may include both polymers and metals. In one embodiment, the connector housing is formed of polymeric materials by methods such as injection molding, extrusion, casting, machining, and the like, while the electrically conductive components are formed of metal by methods such as molding, casting, stamping, machining the like. Material selection will depend upon factors including, but not limited to, chemical exposure conditions, environmental exposure conditions including temperature and humidity conditions, flame-retardancy requirements, material strength, and rigidity, to name a few.

Although specific embodiments have been illustrated and described herein for purposes of description of the preferred embodiment, it will be appreciated by those of ordinary skill in the art that a wide variety of alternate or equivalent implementations may be substituted for the specific embodiments shown and described without departing from the scope of the present invention. Those with skill in the art will readily appreciate that the present invention may be implemented in a very wide variety of embodiments. This application is intended to cover any adaptations or variations of the embodiments discussed herein. Therefore, it is manifestly intended that this invention be limited only by the claims and the equivalents thereof.

What is claimed is:

1. A terminal for use in an electronic connector for establishing electrical contact with a conductive surface on a first printed circuit board, the connector including a housing having a plurality of terminal-receiving cavities, the terminal comprising:
a base section configured for electrical connection with a second printed circuit board; and
a resilient contact beam having a proximal end coupled to the base section and a free distal end, the contact beam shaped to provide a contact section between the proximal end and the distal end, the contact section configured for engaging the conductive surface on the first printed circuit board upon insertion of the first printed circuit board into the housing in a first direction;
wherein the free distal end of the contact beam extends substantially in the first direction.

2. The terminal of claim 1, wherein the free distal end of the contact beam is configured to engage the housing when the first printed circuit board is withdrawn from the housing in a second direction opposite the first direction.

3. The terminal of claim 2, wherein the contact section and the free distal end of the contact beam are oriented to create a moment that reduces normal forces between the contact section and the first printed circuit board when the first printed circuit board is withdrawn in the second direction.

4. The terminal of claim 1, wherein the contact section comprises a curved portion extending substantially transverse to the first direction.

5. An electrical connector for receiving a first printed circuit board having a plurality of conductive surfaces thereon, the connector comprising:
a socket defining an elongated slot having a first side and a second side for receiving the first printed circuit board therein in a first direction; and
a plurality of electrical terminals positioned on at least one of the first and second sides of the slot for engaging the plurality of conductive surfaces on the first printed circuit board;
wherein the terminals each comprise a contact beam configured for engaging a corresponding one of the conductive surfaces on the first printed circuit board, the contact beam having a free end extending substantially in the first direction.

6. The connector of claim 5, wherein the terminals each further comprise a base section supporting the contact beam, the base section configured for electrical connection with a printed circuit board.

7. The connector of claim 5, wherein the free ends of the contact beams are configured to engage the socket when the first printed circuit board is withdrawn from the slot in a second direction opposite the first direction.

8. The connector of claim 7, wherein the contact beams are shaped to rotate about the free ends of the contact beams when the first printed circuit board is withdrawn from the slot in the second direction.

9. The connector of claim 8, wherein rotation about the free ends of the contact beams reduces normal forces between the contact beams and the first printed circuit board.

10. The connector of claim 5, wherein the electrical connector is a memory module connector selected from a double data rate (DDR) memory module connector, a single in-line memory module (SIMM) connector, and a dual in-line memory module (DIMM) connector.

11. The connector of claim 5, wherein the socket comprises a mounting surface configured for engaging a second printed circuit, and wherein the socket is configured to position a bottom edge of the first printed circuit board less than about 3 mm from the mounting surface.

12. The connector of claim 11, wherein the bottom edge of the first printed circuit board is less than about 1.5 mm from the mounting surface.

13. A connector system comprising:
a first printed circuit board having a plurality of conductive surfaces thereon;
a second printed circuit board having a plurality of conductive surfaces thereon; and
an electrical connector mounted on the second printed circuit board, the electrical connector comprising:
a housing defining an elongated slot having a first side and a second side for receiving the first printed circuit board therein in an insertion direction toward the second printed circuit board; and
a plurality of electrical terminals positioned on the first and second sides of the slot for engaging the plurality of conductive surfaces on the first printed circuit board, the plurality of electrical terminals electrically connected to the conductive surfaces on the second printed circuit board;
wherein the terminals each comprise a contact beam configured for engaging a corresponding one of the conductive surfaces on the first printed circuit board, the contact beam having a free end extending substantially toward the second printed circuit board.

14. The connector system of claim 13, wherein the housing comprises a plurality of terminal-receiving cavities positioned on at least one of the first and second sides of the slot, and wherein the electrical terminals are positioned within the terminal receiving cavities.

15. The connector system of claim 13, wherein the terminals each comprise a base section having a first end connected to the second printed circuit board, and a second end extending away from the second printed circuit board and connected to the contact beam.

16. The connector system of claim 15, wherein the free ends of the contact beams are spaced from the housing when the first printed circuit board is inserted into the slot and are configured to engage the housing when the first printed circuit board is withdrawn from the slot.

17. The connector system of claim 16, wherein the contact beams are shaped to form a contact section for engaging conductive surfaces on the first printed circuit board, the contact section positioned between the free end of the contact beam and the base section, and wherein withdrawal of the first printed circuit board from the slot pulls the free end of the contact beam into engagement with the housing.

18. The connector system of claim 13, wherein the electrical connector is a memory module connector selected from a double data rate (DDR) memory module connector, a single in-line memory module (SIMM) connector, and a dual in-line memory module (DIMM) connector.

19. The connector system of claim 13, wherein the electrical connector is configured to position a bottom edge of the first printed circuit board less than about 3 mm from the second printed circuit board.

20. The connector system of claim 19, wherein the bottom edge of the first printed circuit board is less than about 1.5 mm from the second printed circuit board.
